(19) United States
(12) Patent Application Publication
(10) Pub. No.: US 2026/0114320 A1
(43) Pub. Date: Apr. 23, 2026

(54) DIE TO WAFER DIRECT HYBRID BONDING METHOD

(71) Applicants: COMMISSARIAT A L'ENERGIE ATOMIQUE ET AUX ENERGIES ALTERNATIVES, Paris (FR); SET CORPORATION, Saint-Jeoire (FR)

(72) Inventors: Frank FOURNEL, Grenoble Cedex 09 (FR); Loic SANCHEZ, Grenoble Cedex 09 (FR); Noura NADI, Grenoble Cedex 09 (FR); Nicolas RAYNAUD, Saint-Jeoire (FR); Antoine SARCIAT, Saint-Jeoire (FR); Tifenn KERBIRIOU, Saint-Jeoire (FR); Clément CASTAN, Grenoble Cedex 09 (FR)

(73) Assignees: COMMISSARIAT A L'ENERGIE ATOMIQUE ET AUX ENERGIES ALTERNATIVES, Paris (FR); SET CORPORATION, Saint-Jeoire (FR)

(21) Appl. No.: 19/142,842

(22) PCT Filed: Dec. 22, 2023
(86) PCT No.: PCT/EP2023/087618

§ 371 Date: Jun. 24, 2025

(30) Foreign Application Priority Data
Dec. 28, 2022 (FR) FR2214574

(51) Int. Cl. H10W 80/00; H10W 46/00

(52) U.S. Cl. CPC H10W 80/163; H10W 46/301; H10W 80/016; H10W 80/331

(57) ABSTRACT

A die to wafer direct hybrid bonding method includes providing at least one die comprising a first copper pad and a first silicon oxide layer, providing a wafer comprising a second copper pad and a second silicon oxide layer, and handling the die so as to position the face of the die facing the zone for receiving the die on the wafer, by aligning the first and second pads. At least one water drop is deposited in the zone for receiving the die and/or on the face of the die. Pressure on the die is applied to form, from the water drop, a water film between the face and the zone for receiving the die.

### TECHNICAL FIELD OF THE INVENTION

The present invention relates to 3D integration, more specifically, die to wafer direct bonding, and more specifically, die to wafer direct hybrid bonding.

### PRIOR ART

In the field of semiconductor components 3D integration, methods are developed to transfer and assemble a wafer or a die on another wafer. From among these methods, direct bonding and more specifically, hybrid bonding make it possible to assemble two stacked integrated circuits, and/or to establish a direct electric connection between these two integrated circuits via the bonding interface. This makes it possible to increase the interconnecting density of components manufactured by 3D integration.

In particular, copper/oxide hybrid bonding is an industrial bonding technique, typically consisting of bringing together two surfaces composed of silicon oxide-surrounded copper pads. These surfaces composed of two materials are thus called hybrid. The aim of bonding is to perform an electric contact between the copper pads of the two surfaces facing one another. The copper pads have a typical size of a few microns. It is therefore necessary to fully align the two surfaces prior to the direct bonding. Initially developed for a “wafer to wafer” bonding, this hybrid bonding is now developed to perform a “die to wafer” bonding, by resorting to so-called “pick and place” machines, which is the usual meaning retained by a person skilled in the art. This makes it possible to combine a high placing accuracy and a high rate. The document, “Die to Wafer Direct Hybrid Bonding Demonstration with High Alignment Accuracy and Electrical Yields, A. Jouve et al., in 2019 International 3D Systems Integration Conference (3DIC), pp. 1-7” discloses a die to wafer direct hybrid bonding method having a high alignment accuracy with a high yield. A disadvantage of this method is that bonding defects D can appear at certain dies 10_{KO}, as illustrated in FIG. 1.

There is therefore a need to reduce, or even eliminate, the bonding defects for a direct bonding generally and more specifically, for a die to wafer direct hybrid bonding. An aim of the invention is to meet this need.

### SUMMARY OF THE INVENTION

To achieve this aim, according to an embodiment, a die to wafer direct bonding method is provided, comprising at least the following steps:
Providing at least one die having a first flat face, preferably comprising first alignment marks,
Providing at least one wafer having a second flat face comprising a zone for receiving the die, and preferably, second alignment marks,
Handling the die, so as to position the first face of the die facing the zone for receiving the die on the second face of the wafer, by aligning the die opposite the wafer, preferably via the first and second alignment marks,
Putting the first face of the die in contact with the zone for receiving the die, so as to bond the die on the second face of the wafer.

Advantageously, the method comprises, before putting in contact, and preferably before handling the die, a deposition of at least one water drop in the zone for receiving the die on the second face of the wafer and/or on the first face of the die. The water drop does not cover the alignment marks at this stage.

Advantageously, the method also comprises, during the handling of the die and after deposition of the water drop, an application of a pressure on the die configured to form, from the deposited water drop, a water film between the first face and the zone for receiving the die.

According to another embodiment, a die to wafer direct hybrid bonding method is provided, comprising at least the following steps:
Providing at least one die comprising at least one first copper pad and one first silicon oxide layer, said die having a first flat face formed by exposed parts of the first copper pad and of the first silicon oxide layer,
Providing at least one wafer comprising at least one second copper pad and one second silicon oxide layer, said wafer having a second flat face comprising a zone for receiving the die, said zone being formed by exposed parts of the second copper pad and of the second silicon oxide layer,
Handling the die, so as to position the first face of the die facing the zone for receiving the die on the second face of the wafer, by aligning the first and second copper pads,
Putting the first face of the die in contact with the zone for receiving the die, so as to bond the die on the second face of the wafer.

Advantageously, the method comprises, before putting in contact and preferably, before handling the die, a deposition of at least one water drop in the zone for receiving the die on the second face of the wafer, and/or on the first face of the die.

Advantageously, the method also comprises, during the handling of the die, and after deposition of the water drop, an application of a pressure on the die configured to form, from the deposited water drop, a water film between the first face and the zone for receiving the die.

In the scope of the development of the present invention, it has been observed that the formation of the water film by deposition of a water drop and application of a pressure on said water drop advantageously making it possible to remove the bonding defects between the die and the wafer.

Generally, it is counter-indicated and/or counterintuitive to form a liquid interface, in particular, water-based, when an accurate alignment of the die facing the wafer is achieved. It is indeed presumed that the presence of water between the die and the wafer will modify the initial alignment typically achieved by “pick and place”-type precision industrial equipment.

In the scope of the present invention, it has been surprisingly observed that the application of a pressure on the water drop, which makes it possible to form a thin water film, makes it possible to preserve the initial alignment achieved by the equipment. Thus, the formation of a thin water film avoids a misalignment of the die opposite the wafer. This presence of water in a thin layer reduces or removes the bonding defects.

To avoid the bonding defects, a person skilled in the art of direct hybrid bonding, could consider more complex solutions, for example, by performing a handling and the helium-based, vacuum or controlled atmosphere putting into contact, or also to curve dies at the time of bonding. These solutions impose more constraints on industrial equipment and are more expensive. They have not been retained in the scope of the present invention.

The method according to the invention, thus advantageously makes it possible to reduce or remove the bonding defects in direct bonding and in direct hybrid bonding, while controlling the costs.

### BRIEF DESCRIPTION OF THE FIGURES

The aims, objectives, as well as the features and advantages of the invention will best emerge from the detailed description of an embodiment of the latter, which is illustrated by the following accompanying drawings, in which:

FIG. 1 is an acoustic microscopic image illustrating, as a top view, of the bonding defects between a wafer and certain dies assembled by direct hybrid bonding, according to the prior art.

FIGS. 2, 4 and 6 schematically illustrate, as a cross-section, direct hybrid bonding steps, according to an embodiment of the present invention. FIGS. 3 and 5 schematically illustrate, as a top view, direct hybrid bonding steps, according to an embodiment of the present invention.

FIG. 7 is an acoustic microscopic image, illustrating, as a top view, dies assembled on a wafer by direct hybrid bonding, according to an embodiment of the present invention.

The drawings are given as examples, and are not limiting of the invention. They constitute principle schematic representations, intended to facilitate the understanding of the invention, and are not necessarily to the scale of practical applications. In particular, on the principle diagrams, the thicknesses and/or the dimensions of the different layers, patterns and raised elements are not representative of reality.

### DETAILED DESCRIPTION OF THE INVENTION

Before starting a detailed review of embodiments of the invention, optional features are stated below, which can optionally be used in association or alternatively:

According to an example, the first flat face and the zone for receiving the die are with the basis of one same material, for example, Si, Ge, AsGa, InP, GaN, SiC, Al₂O₃, diamond, SiO₂, Si₃N₄, SICN, Al₂O₃, TiN, TaN, WN, Cu, Ti, Ni, Au, W.

According to an example, the die comprises at least one first pad with the basis of a first material and a first layer with the basis of a second material, and the first flat face is formed by exposed parts of the first pad and of the first layer.

According to an example, the wafer comprises at least one second pad with the basis of the first material and a second layer with the basis of the second material, and the zone for receiving the die is formed by exposed parts of the second pad and of the second layer.

According to an example, the method is a die to wafer direct hybrid bonding method.

According to an example, the first material is chosen from among copper, titanium, nickel, gold, tungsten.

According to an example, the second material is chosen from among SiO₂, Si₃N₄, SICN, Al₂O₃, TiN, TaN, WN.

According to an example, the water film extends over the second face, by remaining within the zone for receiving the die.

According to an example, the second alignment marks are disposed in the zone for receiving the die. The alignment is performed typically by inserting a microscope lens between the second alignment marks of the zone for receiving the die, and the first alignment marks of the first flat face of the die. After alignment, the microscope lens is removed and the die and the zone for receiving the die are put into contact via the water film. According to an example, the deposition of the at least one water drop is configured, such that the at least one water drop does not totally cover said first and/or second alignment marks.

According to an example, the water film extends over the second face, outside of the zone for receiving the die. It is not necessary that the water film is confined to the zone for receiving the die. In particular, it is not necessary to provide hydrophobic zones at the perimeter of the zone for receiving the die. This avoids having to specifically prepare the second face of the wafer and/or the first face of the die to proceed with the bonding.

According to an example, the second face has a so-called peripheral zone at the perimeter of the zone for receiving the die, said peripheral zone and the zone for receiving the die both being hydrophilic. This makes it possible for the water film to extend freely outside of the zone for receiving the die. This makes it possible to discharge excess water during the formation of the water film between the first face of the die and the zone for receiving the die on the wafer.

According to an example, the water film has a thickness less than or equal to 10 μm, preferably less than 1 μm, and more preferably, less than 100 nm or less than 50 nm. This makes it possible to avoid that the die is driven by the water outside of its alignment position with the zone for receiving the die.

According to an example, the deposited water drop initially occupies, before application of pressure, a surface S₃₀ on the zone for receiving the die which is a lot smaller, i.e. at least twice smaller, than the surface S₂₁₀ corresponding to the zone for receiving the die. The water drop can be typically centred on the zone for receiving the die. It is not necessary to cover the entire surface of the zone for receiving the die, during the deposition of the water drop. According to an example, the water drop is deposited on the first flat face of the die and initially occupies, before application of pressure, a surface S₃₀ on the first flat face which is a lot smaller, i.e. at least twice smaller, than the surface of said first flat face of the die.

According to an example, the application of pressure makes it possible to spread the water drop on and outside of the zone for receiving the die, to form the water film between the first face and the zone for receiving the die. This pressure is applied voluntarily, typically by “pick and place” equipment. This pressure is not only due to the weight of the die or to the surface tension forces of the water drop.

According to an example, the second face and/or the first face comprise alignment marks. This makes it possible to accurately align the die with the zone for receiving the die, typically during the use of “pick and place”-type industrial equipment.

According to an example, the first face comprises first alignment marks. According to an example, the second face comprises second alignment marks in the zone for receiving the die. According to an example, the first and/or the second alignment marks are configured to align the die with the zone for receiving the die, through a microscope or a semi-transparent lens inserted between the die and the zone for receiving the die.

According to an example, the deposited water drop has a volume chosen, such that after natural spreading of the water drop over the zone for receiving the die, the water drop does not cover the second alignment marks. According to an example, the deposited water drop has a volume chosen, such that after natural spreading of the water drop over the first face of the die, the water drop does not cover the first alignment marks.

According to an example, the deposited water drop has a volume of between 1 pL and 100 μL, preferably between 8 nL and 10 μL.

According to an example, the deposited water drop has a volume less than or equal to 100 μL. According to an example, the deposited water drop has a volume greater than or equal to 8 nL. According to an example, the deposited water drop has a volume less than or equal to 10 μL.

According to an example, the pressure applied is maintained for a duration of between 100 ms and 10 s, preferably for 1 s. This makes it possible to form a water film, by reducing the risks that this water film drives the die outside of the initial alignment position of the die. This also makes it possible to obtain a placement rate which is compatible with industrial requirements.

According to an example, the relative humidity of the atmosphere is controlled, so as to be greater than or equal to 80% during the handling of the die. This makes it possible to limit the evaporation of the deposited water drop, before application of pressure on said water drop. The evolution of the volume of the water drop is thus better controlled. The volume of the water drop can thus be reduced. This makes it possible to apply the method to very small-sized dies, having, for example, a first face surface area of around 100*100 μm².

According to an example, the method further comprises a drying step after application of pressure, configured to remove the water film. The putting into contact, i.e. the direct bonding or the direct hybrid bonding, is thus performed. This drying can be performed by simple storage under an ambient atmosphere. Alternatively, it can be performed under a dry atmosphere, in a dryer, for example, or under a neutral gas atmosphere, for example, under nitrogen, or under argon or under helium. A relative humidity less than 1% can thus be obtained. It is also possible to perform this drying, by putting the wafer under vacuum, for example, at 20 mbar of pressure at 21° C. It is preferable to not fall below the saturating vapour pressure of water. It is also possible to increase the temperature, for example, to 75° C. It is preferable to not exceed the boiling point of water.

According to an example, the method further comprises an annealing step, intended to improve or reinforce the bonding, after the putting into contact.

In the scope of the present invention, a method for transferring and bonding one or more dies on one single and unique wafer is described. This method is preferably intended for an industrial implementation, to transfer and bond a plurality of dies on each wafer of a plurality of wafers. It belongs to the field of direct hybrid bonding. “Hybrid” means that the bonding surfaces are composed of at least two materials. “Direct” means that the bonding interface corresponds, after final bonding, directly to the bonding surfaces, without there being a bonding layer, like a polymer glue, inserted between the two bonding surfaces.

In the present application, a “die” typically means an integrated circuit comprising microelectronic or optoelectronic components, or also electromechanical microsystems (MEMS). A “wafer” typically means a substrate comprising or carrying a plurality of dies. A die can also, by extension, mean a wafer piece with no components. The alignment can be performed with alignment marks or, in the latter case, simply with the movement accuracy of the machine. The alignment is performed typically with an accuracy of 100 μm or better.

The zone for receiving the die is also called bonding zone below.

It is specified that, in the scope of the present invention, the terms “on”, “surmounts”, “covers”, “underlying”, “opposite” and their equivalents do not necessarily mean “in contact with”. Thus, for example, the deposition, the transfer, the bonding, the assembly or the application of a first layer on a second layer, does not compulsorily mean that the two layers are directly in contact with one another, but means that the first layer covers, at least partially, the second layer by being either directly in contact with it, or by being separated from it by at least one other layer or at least one other element.

A layer can, moreover, be composed of several sublayers of one same material or of different materials.

By a substrate, a film, a layer “with the basis” of a material A, this means a substrate, a film, a layer comprising this material A only, or this material A and optionally other materials, for example, doping elements or alloy elements.

A water drop according to the invention is preferably composed of pure or deionised water (DI water). In particular, it does not comprise particles of a size greater than 20 nm. It preferably has a resistivity greater than 1 MOhm.

The hybrid surface of the die or of the wafer can be constituted of different materials:
Copper, titanium, nickel, gold, tungsten, for example (these metals being able to oxidised on the surface or not), SiO₂, Si₃N₄, SICN, Al₂O₃, TiN, TaN, WN, for example.

The surface of the die cannot be hybrid and be composed of one single material (Si, Ge, AsGa, InP, GaN, SiC, Al₂O₃, diamond, SiO₂, Si₃N₄, SICN, Al₂O₃, TiN, TaN, WN, copper, titanium, nickel, gold, tungsten, for example).

The surface of the wafer cannot be hybrid and be composed of one single material (Si, Ge, AsGa, InP, GaN, SiC, Al₂O₃, diamond, SiO₂, Si₃N₄, SICN, Al₂O₃, TiN, TaN, WN, copper, titanium, nickel, gold, tungsten, for example).

Several embodiments of the invention implementing successive steps of the manufacturing method are described below. Unless explicitly mentioned, the adjective “successive” does not necessarily imply, even if this is generally preferred, that the steps immediately follow one another, intermediate steps being able to separate them.

Moreover, the term “step” means the carrying out of a part of the method, and can mean a set of substeps.

Moreover, the term “step” does not compulsorily mean that the actions performed during a step are simultaneous or immediately successive. Certain actions of a first step can, in particular, be followed by actions linked to a different step, and other actions of the first step can then be resumed. Thus, the term “step” does not necessarily mean single and inseparable actions over time, and in the sequence of phases of the method.

A preferably orthonormal system, comprising the axes x, y, z is represented in the accompanying figures. When one single system is represented on one same set of figures, this system applies to all the figures of this set.

In the present patent application, thickness will preferably be referred to for a layer or a film. The thickness is taken along a direction normal to the main extension plane of the layer or of the film. Thus, a layer or a film typically has a thickness along z. The relative terms “on”, “surmounts”, “under”, “underlying” refer to positions taken along the direction Z.

An element located “in vertical alignment with” or “to the right of” another element means that these two elements are both located on one same line perpendicular to a plane into which a lower or upper face of a substrate mainly extends, i.e. over one same line oriented vertically in the figures in a cross-section.

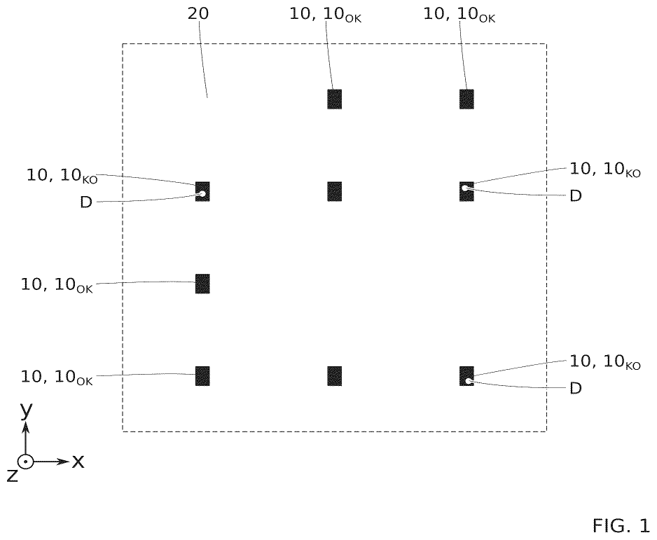

FIG. 1 corresponds to an acoustic microscopic image produced after direct hybrid bonding of dies 10 on a wafer 20, according to a standard direct hybrid bonding method. On the new dies 10 bonded on this wafer 20 zone, six dies 10_{OK} have a normal bonding, without apparent defects, and three dies 10_{KO} have bonding defects D. The method according to the invention aims to remove these bonding defects.

A principle of the method according to the invention is to insert a water drop between the die and the wafer and to apply a pressure on this water drop, so as to form a thin water film between the die and the wafer. Surprisingly, the alignment of the die opposite the wafer is preserved in the presence of this thin water film. During the drying of the water film, the die comes into direct contact with the wafer and the bonding is performed without defects.

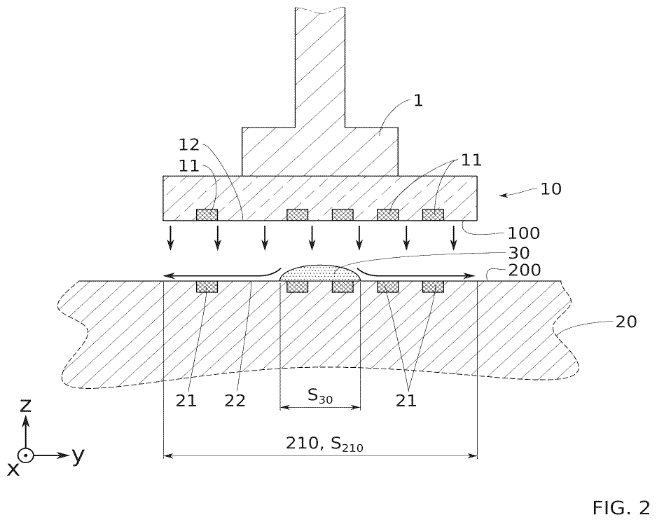

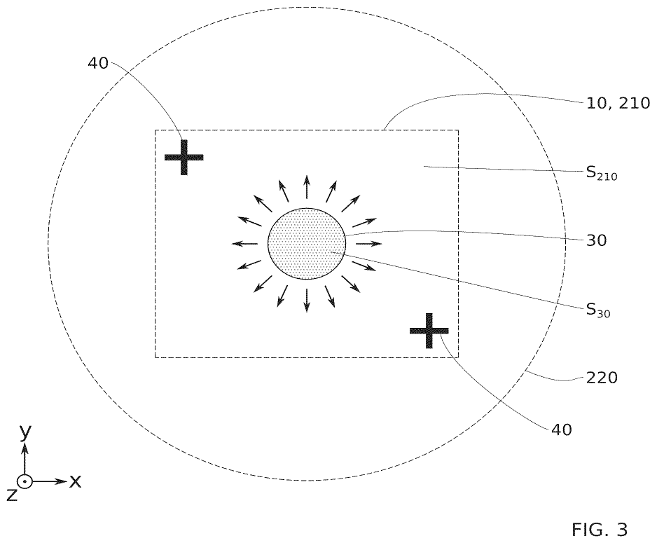

FIG. 2 to 6 Illustrate Certain Steps of the Direct Hybrid Bonding Method According to the invention.

As illustrated in FIG. 2, a die 10 comprising copper pads 11 at least partially integrated within a silicon oxide layer 12 is brought by a “pick and place” device 1 facing a wafer 20. The face 100 of the die 10 is flat and is composed, in particular, of exposed parts of the copper pads 11 and of exposed parts of the silicon oxide layer 12. The face 100 is therefore a composite or hybrid face having a surface formed partially by the flush copper pads 11, and the parts of the exposed layer 12.

The face 200 of the wafer 20 facing the die 10 is substantially identical to the face 100, at least at the zone 210 for receiving the die 10. In this zone 210, the face 200 is flat and is composed, in particular, exposed parts of the copper pads 21 and exposed parts of the silicon oxide layer 22. At the zone 210, the face 200 is therefore like the face 100, a composite or hybrid face having a surface formed partially by the flush copper pads 21 and the parts of the exposed layer 22.

The “pick and place” device 1 makes it possible to handle the die 10, so as to align the pads 11 of the die 10 in vertical alignment with the pads 21 of the wafer 20. This alignment can typically be performed through first alignment marks positioned on the die 10 (not illustrated) and/or second alignment marks 40 positioned on the wafer 20, in the zone 210, as illustrated as a top view in FIG. 3. The alignment is typically performed using a microscope that is placed between the die 10 and the wafer 20, and which enables a simultaneous observation of the first and second alignment marks. After the alignment, the microscope is removed and the die 10 is descended up to the putting into contact with the receiving zone 210, by flattening the water drop to form a water film inserted between the die 10 and the zone 210. Pick and place devices are generally equipped with such a microscope. This is the case, for example, of the NEO HB device commercialised by the company SET. In FIG. 3, the first and second alignment marks are cross-shaped, which are superposed after alignment. In a variant, the first and second alignment marks can be complementary. For example, the second alignment marks 40 are constituted of a cross (as in FIG. 3) and the first alignment marks are constituted of four disconnected squares, which, after alignment, are positioned complementarily from the cross to form a square. Before or during the handling of the die 10 by the “pick and place” device 1, a water drop 30 is deposited on at least one of the faces 100, 200 facing one another. According to an option, the water drop 30 is deposited only in the zone 210, for example, at the centre of the zone 210. According to another option, the water drop 30 is deposited or formed only on the face 100 of the die 10, for example, at the centre of the face 100. According to another option, a first water drop 30 is deposited or formed on the face 100, and a second water drop 30 is deposited or formed on the zone 210. The principle of this step of the method is to insert at least one water drop between the face 100 and the zone 210 intended to come into contact with one another.

The volume of the water drop 30 is preferably quite low. Generally, this volume can be between 1 pL and 100 μL, preferably between 8 nL and 10 μL. These values correspond typically to a drop volume obtained in one single deposition. The step of depositing the drop can be repeated several times to increase the total volume deposited.

If the drop is disposed before alignment, the volume of the water drop 30 is to adapt, according to the surface S₂₁₀ of the bonding zone, such that the surface S₂₁₀ of the bonding zone is partially covered at least over 1%, even 10% or 25% of its surface, or more specifically, at least at 50% of its surface by the drop by considering its natural spreading, but must not cover the alignment marks, in order to enable alignment.

If the drop is disposed after alignment, there is less constraint on its volume.

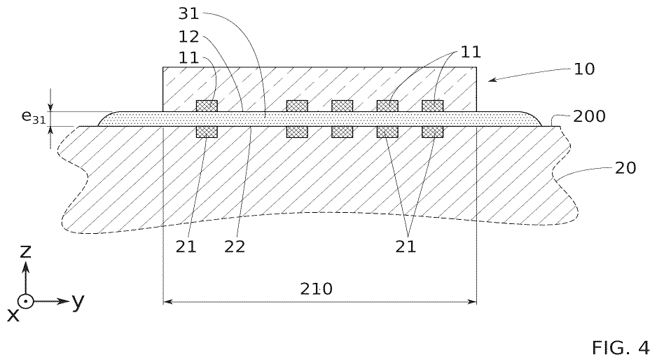

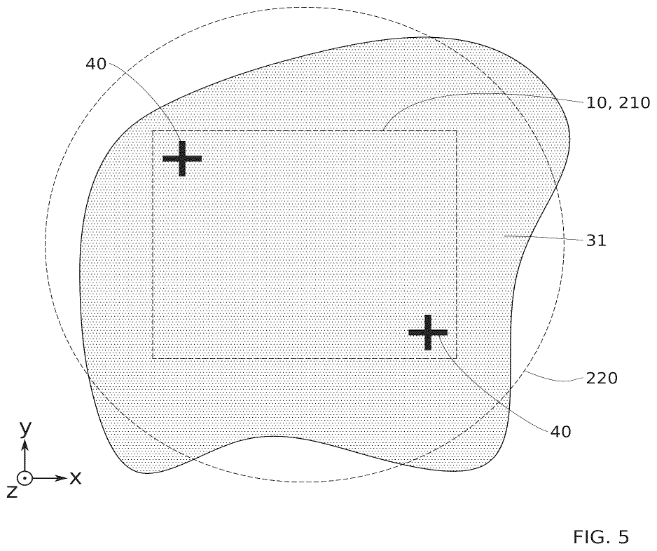

In any case, after flattening the water drop, the water film 31 thus formed can cover the entire surface S₂₁₀ of the bonding zone (as illustrated in FIG. 4 and FIG. 5) or only a part (10% even 25% even 50%) of this surface.

The lower the volume of the water drop 30 is, the more rapid this will evaporate. The handling of the die 10 and the accurate alignment of the die 10 opposite the zone 210 can take a certain time, for example, around a few seconds or tens of seconds. Choosing the volume of the water drop 30 can consider this handling time during which the drop 30 starts to evaporate. The volume of the water drop 30 is preferably sufficiently high, to compensate for the water losses by evaporation and to cover the entire surface S₂₁₀ or at least 1%, or more specifically at least 10, 25 or 50%, of the bonding zone under the effect of the pressure exerted by the die 10 during the following step of the method.

A compromise in choosing the volume of the water drop 30 can therefore be found, according to the size of the die 10, and/or according to the distance between the initial position of the drop and the alignment marks, and/or according to the distance between two neighbouring zones 210 for receiving dies, and/or according to the handling and alignment time. According to an example, for a die 10 of 3*3 mm² and for alignment marks 40 located at 100 μm inside the corners or the edges of the zone 210, a reasonable volume for the water drop 30 is around 520 nL. According to an option, this is according to the surface S₃₀ that the drop 30 occupies on the zone 210 during the deposition and after its natural spreading that is chosen, the drop volume to be dispensed. The surface S₃₀ that occupies the drop 30 after its natural spreading without specific pressing, is preferably at least twice less than the surface S₂₁₀ of the zone 210, even at least ten times less.

It is possible to slow down the evaporation kinetics of the water drop 30 by increasing the relative humidity of the atmosphere of the “pick and place” machine. This makes it possible to reduce the necessary drop volume. Under an atmosphere having a relative humidity RH value of around 90%, for example, the drop 30 can have a volume of a few tens of picolitre (pL) only. The size of the drop 30 is thus reduced. This makes it possible to implement the method for very small sized dies, for example, around 100*100 μm².

When the drop is deposited or formed and when the alignment is performed, the “pick and place” device 1 is lowered in the direction of the zone 210. In the case illustrated in FIG. 2, the face 100 therefore first comes into contact with the drop 30, which has the effect of spreading the drop 30 over the zone 210.

The “pick and place” device 1 then applies a pressure on the drop 30, such that the drop 30 is spread over the entire zone 210, or at least over 1%, or more specifically, over 50% of the zone 210, to form a water film 31 between the face 100 and the zone 210, as illustrated in FIGS. 4 and 5. During the application of this pressure, some of the water is typically ejected outside of the bonding zone 210. The water film 31 extends beyond the zone 210. This does not impede the invention. It is not necessary to confine the water or the water film 31 in the zone 210. The zone 220 at the periphery of the zone 210 can be hydrophilic, like the zone 210. This avoids having to specifically prepare the peripheral zone 220. In particular, it is not necessary to provide hydrophobic zones at the peripheral zone 220, nor even a particular topography like a step, which could confine the drop in the zone 210. The implementation of the method is facilitated.

The pressure exerted by the “pick and place” device 1 must be sufficient to obtain a water film 31 of low thickness e₃₁. The thickness e₃₁ of the residual water film 31 is typically less than 5 μm, preferably less than 1 μm and more specifically, less than 100 nm or less than 50 nm. To obtain such a thickness e₃₁, a force of between 0.1N and 1 kN, preferably of between 1N and 300N, is applied to the “pick and place” device. A pressing pressure of a few tens to a few thousands of pascals (Pa) is thus exerted on the water film 31.

According to an example, the pressure exerted on the water film 31 is around 10⁴ to 3.10⁶Pa for a square die of 10 mm*10 mm subjected to a force of 1 to 300N. For a die of 1 mm*1 mm, the pressure varies from 10⁶ to 3.10⁸ Pa.

The pressure exerted on the water film 31 is maintained for a duration of between 100 ms and 10 s, preferably between 500 ms and 5 s. According to an example, the pressure exerted on the water film 31 is maintained for a duration of around 1 s. This duration is fully compatible with the industrial implementation of the method. The “pick and place” device 1 is then removed, typically to go and handle another die and perform another bonding according to the method. Advantageously, during the removal of the “pick and place” device 1, the alignment between the die 10 and the zone 210 is preserved in the presence of the thin film 31.

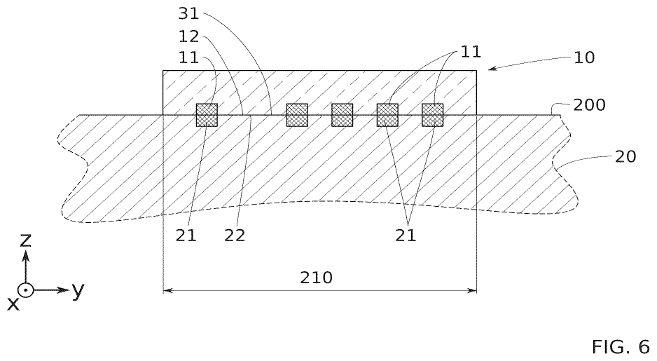

As illustrated in FIG. 6, the water film 31 disappears by drying and the die 10 is in direct contact with the zone 210. The direct hybrid bonding of the die 10 on the zone 210 is thus at least partially performed. The drying of the water film 31 can correspond to a simple storage in an atmosphere having a relative humidity (HR) less than 100%, and preferably less than 50%. It is also possible to perform the drying in a very dry atmosphere (HR<1%), and/or in a neutral gas atmosphere like nitrogen, argon or helium, for example. It is also possible to obtain a dry air with a dryer. It is also possible to perform this drying by putting the wafer under vacuum, in an atmosphere having a pressure less than ambient pressure, for example, at 20 mbar of pressure and at an ambient temperature of 21° C. It is preferable to not fall below the saturating vapour pressure of water. It is also possible to increase the temperature during drying, for example, up to 75° C. It is preferable to not exceed the boiling point of water.

After drying, a conventional annealing for the direct hybrid bonding can be performed, for example, to 300° C. for 2 hours. This bonding reinforcing annealing is advantageously performed at a temperature greater than 200° C., even 250° C., and advantageously of between 200° C. and 400° C., and typically between 250° C. and 350° C.

According to a particular example of an implementation of the method, all the steps are carried out in a clean room at 21° C. and 45% relative humidity. The hybrid surfaces of the face 100 and of the zone 210 are composed of silicon oxide-surrounded copper pads, typically according to an embodiment described in the document, “Die to Wafer Direct Hybrid Bonding Demonstration with High Alignment Accuracy and Electrical Yields, A. Jouve et al., in 2019 International 3D Systems Integration Conference (3DIC), pp. 1-7”. The size of each die 10 is 3*3 mm². An NEO HB “pick and place” machine of the company SET is used. It is modified to include a NanoJet water drop distributer (with an NJ-K-4010 piezoelectric valve) of the company Microdrop. Before starting the alignment of the die 10 and of the wafer 20, a water drop 30 of 520 nL is deposited on the wafer 20 at the centre of the zone 210 for receiving the die 10. The water drop 30 does not cover the alignment marks 40 which are located beyond the corners of the bonding zone 210. The alignment is performed at least of 5 s and the die 10 is put into contact with the water drop 30. A 20N force is applied on the die 10, which corresponds to a pressure exerted of around 2.2 GPa. The pressure is maintained for 1 s. The method is repeated to bond a plurality of dies 10 on the wafer 20. The wafer 20 is then exited from the “pick and place” machine and stored in the atmosphere of the clean room for 24 hours. After storage, an annealing at 300° C. for 2 hours is performed in a furnace.

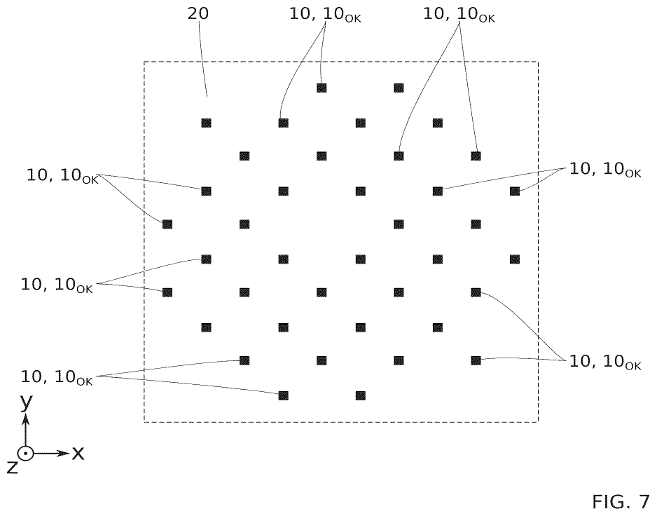

FIG. 7 is an image produced using a scanning acoustic microscopy (SAM) on the wafer 20 carrying the dies 10, in order to characterise the quality of the direct hybrid bonding. It clearly appears that all of the dies 10, 10_{OK} are fully bonded without interface defects by the method according to the invention.

In view of the description above, it clearly appears that the proposed method offers a particularly effective solution for die to wafer direct hybrid bonding.

The invention is not limited to the embodiments described above.

1-16. (canceled)

17. A die to wafer direct bonding method, comprising:
providing at least one die having a first flat face, providing at least one wafer having a second flat face comprising a zone for receiving the die,
handling the die, so as to position the first face of the die facing the zone for receiving the die on the second face of the wafer by aligning the die opposite the wafer,
putting the first face of the die in contact with the zone for receiving the die, so as to bond the die on the second face of the wafer,
before putting into contact, a deposition of at least one water drop in the zone for receiving the die on the second face of the wafer and/or on the first face of the die, and during the handling of the die and after deposition of the water drop, an application of a pressure on the die configured to form, from the deposited water drop, a water film between the first face and the zone for receiving the die, the application of the pressure on the die being configured, such that the position of the die opposite the wafer is not modified, due to presence of water between the die and the wafer,
drying after application of pressure, to remove the water film and bring the die into contact with the wafer, the drying being carried out at a temperature strictly less than 100° C., and
after the drying, performing annealing configured to reinforce the bonding of the die on the wafer,
wherein the second face has a peripheral zone at a perimeter of the zone for receiving the die, the peripheral zone and the zone for receiving the die both being hydrophilic.

18. The method according to claim 17, wherein:
the die comprises at least one first pad based upon a first material and a first layer based upon a second material, and the first flat face is formed by exposed parts of the first pad and of the first layer,
the wafer comprises at least one second pad based upon the first material and a second layer based upon the second material, and the zone for receiving the die is formed by exposed parts of the second pad and of the second layer, and
the method being a die to wafer direct hybrid bonding method.

19. The method according to claim 18, wherein the first material is chosen from among copper, titanium, nickel, gold, and tungsten, and wherein the second material is chosen from among SiO₂, Si₃N₄, SiCN, Al₂O₃, TiN, TaN, and WN.

20. The method according to claim 17, wherein the first flat face comprises first alignment marks and the second flat face comprises second alignment marks, and wherein the alignment of the die opposite the wafer is performed via the first and second alignment marks.

21. The method according to claim 20, wherein the second alignment marks are disposed in the zone for receiving the die, and wherein the deposition of the at least one water drop is configured such that the at least one water drop does not totally cover the second alignment marks.

22. The method according to claim 17, wherein the water film extends over the second face, outside of the zone for receiving the die.

23. The method according to claim 17, wherein the water film extends over the second face, by remaining within the zone for receiving the die.

24. The method according to claim 17, wherein the water film has a thickness less than 5 μm.

25. The method according to claim 17, wherein the deposited water drop initially occupies, before application of pressure, a surface on the zone for receiving the die which is smaller, than a surface corresponding to the zone for receiving the die, and the application of pressure spreads the water drop on and outside of the zone for receiving the die, to form the water film between the first face and the zone for receiving the die.

26. The method according to claim 17, wherein the deposited water drop has a volume less than or equal to 100 μL.

27. The method according to claim 17, wherein the deposited water drop has a volume of between 8 nL and 10 μL.

28. The method according to claim 17, wherein the pressure applied is maintained for a duration of between 100 ms and 10 s.

29. The method according to claim 17, wherein a relative humidity of the atmosphere is controlled so as to be greater than or equal to 80% during the handling of the die.

30. The method according to claim 17, wherein the drying step is carried out at ambient temperature.

31. The method according to claim 17, wherein the annealing step is carried out at a temperature greater than or equal to 300° C. for a duration greater than or equal to 2 hours.

32. The method according to claim 17, wherein the water film has a thickness less than 50 nm.
